(19) United States
(12) Patent Application Publication
(10) Pub. No.: US 2024/0057275 A1
(43) Pub. Date: Feb. 15, 2024

(54) VEHICLE COMPUTE UNIT WITH MIDDLE PLATE ARCHITECTURE

(71) Applicant: NIO Technology (Anhui) Co., Ltd., Hefei (CN)

(72) Inventors: Tseng-Mau Yang, South Lake Tahoe, CA (US); Waylon Y. Chen, San Jose, CA (US)

(73) Assignee: NIO Technology (Anhui) Co., Ltd., Hefei (CN)

(21) Appl. No.: 18/232,982

(22) Filed: Aug. 11, 2023

Related U.S. Application Data
(60) Provisional application No. 63/397,121, filed on Aug. 11, 2022.

(51) Int. Cl. H05K 7/14; H05K 7/20

(52) U.S. Cl. CPC H05K 7/1428; H05K 7/20254; H05K 7/20336; H05K 7/20872; H05K 7/20881

(57) ABSTRACT

An assembly for stacking a plurality of circuit boards of an electronics package is provided. The assembly may comprise a chassis structure, a first plurality of printed circuit board (PCB), and a second plurality of PCBs, where the second plurality of PCBs are configured to be coupled to connectors of the first plurality of PCBs that are accessible via connection access points in the chassis structure. The first plurality of PCBs is positioned on a first side of the chassis structure, and the second plurality of PCBs are positioned on a second side of the chassis structure. Positioning tolerancing of the second plurality of PCBs relative to the first plurality of PCBs is provided by the connectors of the first plurality of PCBs.

### CROSS-REFERENCE TO RELATED APPLICATIONS

The present application claims the benefit of and priority, under 35 U.S.C. § 119(e), to U.S. Provisional Application Ser. No. 63/397,121, filed on Aug. 11, 2022, entitled “VEHICLE COMPUTE UNIT WITH MIDDLE PLATE STRUCTURE”, the entire disclosure of which is hereby incorporated herein by reference, in its entirety, for all that it teaches and for all purposes.

### FIELD OF THE DISCLOSURE

The present disclosure is generally directed to electronics packaging, in particular, toward a middle plate architecture for electronics packages and processing units.

### BACKGROUND

Modern electronic component assemblies or electronics packages such as printed circuit board assemblies may include one or multiple processing units (e.g., microprocessors, chips, integrated circuits, system on chips (SOCs), or the like) on a printed circuit board (PCB) or other circuit substrate that sit inside an enclosure. In some examples, the electronics package may include a motherboard (e.g., a first circuit board, a main PCB, etc.) and one or more daughter cards (e.g., additional PCBs, additional circuit boards, daughterboards, PCB daughter cards, etc.), where the one or more daughter cards are coupled to the motherboard (e.g., via headers, pin headers, sockets, board-to-board connectors, or additional types of connectors). The one or more daughter cards may provide complementary or supplementary functions to the motherboard. For example, the one or more daughter cards may include types of circuit boards that plug in or are coupled to the motherboard or similar expansion card (e.g., circuit board) to extend features and services of the motherboard or similar expansion card.

Traditionally, mechanical standoffs are used to mount daughter cards onto a motherboard to form a mezzanine (e.g., tiered) structure where the respective processing units are parallel to each other. One or multiple daughter cards can be mounted onto one main motherboard. In some examples, the mechanical standoffs are simple cylindrical shaped metal components that may or may not have threads for mounting screws for mounting the daughter cards to the motherboard. The mechanical standoffs are controlled to a very tight height tolerance to ensure connectors between the respective processing units are mated correctly with a high precision and accuracy.

### BRIEF SUMMARY

Example aspects of the present disclosure include:

A middle plate structure for an electronics package, comprising: a chassis structure including a frame; a first plurality of cavities defined within the frame on a first side of the chassis structure, the first plurality of cavities being configured to receive a first plurality of printed circuit boards from a first direction; a second plurality of cavities defined within the frame on a second side of the chassis structure, the second plurality of cavities being configured to receive a second plurality of printed circuit boards from a second, different direction; and one or more connection access points connecting the second plurality of cavities to the first plurality of cavities.

Any of the aspects herein, wherein the first plurality of cavities are configured to at least partially contour to conform to the first plurality of printed circuit boards, wherein the second plurality of cavities are configured to at least partially contour to conform to the second plurality of printed circuit boards, and wherein the second plurality of cavities include surfaces upon which the second plurality of printed circuit boards are seated.

Any of the aspects herein, the chassis structure further comprising one or more separators, wherein the one or more separators and the frame define the second plurality of cavities. Optionally, the one or more separators are formed with the frame.

Any of the aspects herein, wherein the second plurality of cavities are configured to receive one or more thermal spacers that are inserted from the second, different direction.

Any of the aspects herein, the chassis structure further comprising: at least one aperture within the chassis structure, wherein the at least one aperture is operable to transfer heat from at least one of the first plurality of printed circuit boards and the second plurality of printed circuit boards to a cooling structure for dissipation into a surrounding environment.

Any of the aspects herein, wherein at least one of: the first printed circuit board is configured to be physically coupled to the second side of the chassis structure; and the one or more additional printed circuit boards are configured to be physically coupled to the first side of the chassis structure.

Any of the aspects herein, wherein a plurality of connectors electrically connect the first plurality of printed circuit boards to the second plurality of printed circuit boards via the one or more connection access points, and wherein position tolerancing of the second plurality of printed circuit boards relative to the first plurality of printed circuit boards is provided by the plurality of connectors on the first plurality of printed circuit boards accessible by the second plurality of printed circuit boards via the one or more connection access points.

Any of the aspects herein, wherein position tolerancing of the second plurality of printed circuit boards relative to the first plurality of printed circuit boards is provided by at least one positioning component on the chassis structure, and wherein the at least one positioning component is operable to engage at least one of the first plurality of printed circuit boards and the second plurality of printed circuit boards.

Any of the aspects herein, wherein the second, different direction is an opposite direction to the first direction.

An electronics package, comprising: a first plurality of printed circuit boards; a second plurality of printed circuit boards; and a middle plate structure, the middle plate structure comprising: a chassis structure including a frame; a first plurality of cavities defined within the frame on a first side of the chassis structure, the first plurality of cavities being configured to receive the first plurality of printed circuit boards from a first direction; a second plurality of cavities defined within the frame on a second side of the chassis structure, the second plurality of cavities being configured to receive the second plurality of printed circuit boards from a second, different direction; and one or more connection access points connecting the second plurality of cavities to the first plurality of cavities.

Any of the aspects herein, further comprising: a coldplate; a heatpipe assembly; and a bottom cover, wherein alignment of the coldplate and the middle plate structure positions the heatpipe assembly proximate to the second side of the middle plate structure, and wherein the bottom cover is operable to be positioned proximate to the first side of the middle plate structure.

Any of the aspects herein, the coldplate comprising at least one protrusion, and the chassis structure comprising at least one aperture within the chassis structure, wherein the at least one aperture is operable to transfer heat from at least one of the first plurality of printed circuit boards and the second plurality of printed circuit boards via the at least one protrusion for dissipation into a surrounding environment via the heatpipe assembly.

Any of the aspects herein, wherein the second plurality of cavities are configured to at least partially contour to conform to the second plurality of printed circuit boards.

Any of the aspects herein, wherein the first plurality of cavities are configured to at least partially contour to conform to the first plurality of printed circuit boards, wherein the second plurality of cavities are configured to receive one or more thermal spacers from the second, different direction, and wherein the one or more thermal spacers are positioned proximate to the second plurality of printed circuit boards, and wherein the second plurality of cavities include surfaces upon which the second plurality of printed circuit boards are seated.

Any of the aspects herein, the chassis structure further comprising one or more separators, wherein the one or more separators and the frame define the second plurality of cavities. Optionally, the one or more separators are formed with the frame.

Any of the aspects herein, wherein a plurality of connectors electrically connect the first plurality of printed circuit boards to the second plurality of printed circuit boards via the one or more connection access points, and wherein position tolerancing of the second plurality of printed circuit boards relative to the first plurality of printed circuit boards is provided by the plurality of connectors on the first plurality of printed circuit boards accessible by the second plurality of printed circuit boards via the one or more connection access points.

Any of the aspects herein, wherein position tolerancing of the second plurality of printed circuit boards relative to the first plurality of printed circuit boards is provided by at least one positioning component on the chassis structure, and wherein the at least one positioning component is operable to engage at least one of the first plurality of printed circuit boards and the second plurality of printed circuit boards.

Any of the aspects herein, wherein the second, different direction is an opposite direction to the first direction.

A method for assembling an integrated electronics package, the method comprising: providing a middle plate structure, wherein the middle plate structure comprises: a chassis structure including a frame; a first plurality of cavities defined within the frame on a first side of the chassis structure; a second plurality of cavities defined within the frame on a second side of the chassis structure; and one or more connection access points connecting the second plurality of cavities to the first plurality of cavities, aligning a first plurality of printed circuit boards with the first plurality of cavities of the middle plate structure from a first direction; aligning a second plurality of printed circuit boards with the second plurality of cavities of the middle plate structure from a second, different direction; and coupling the second plurality of printed circuit boards to the first plurality of printed circuit boards via the one or more connection access points to form a subassembly from the middle plate structure, the first plurality of printed circuit boards, and the second plurality of printed circuit boards.

Any of the aspects herein, further comprising: aligning a bottom cover with the formed subassembly positioned proximate to the first side of the middle plate structure; coupling the bottom cover to the formed subassembly; aligning a coldplate and a heatpipe assembly with the formed subassembly, wherein alignment of the coldplate and the middle plate structure positions the heatpipe assembly proximate to the second side of the middle plate structure; and coupling the coldplate and the heatpipe assembly to the formed subassembly.

Any of the aspects herein, the coldplate comprising at least one protrusion, and the chassis structure comprising at least one aperture within the chassis structure, wherein the at least one aperture is operable to transfer heat from at least one of the first plurality of printed circuit boards and the second plurality of printed circuit boards via the at least one protrusion for dissipation into a surrounding environment via the heatpipe assembly.

Any of the aspects herein, wherein one or more thermal spacers are positioned within the second plurality of cavities proximate to the second plurality of printed circuit boards prior to coupling the coldplate and the heatpipe assembly to the formed subassembly.

Any of the aspects herein, wherein a plurality of connectors electrically connect the first plurality of printed circuit boards to the second plurality of printed circuit boards via the one or more connection access points, and wherein position tolerancing of the second plurality of printed circuit boards relative to the first plurality of printed circuit boards is provided by the plurality of connectors on the first plurality of printed circuit boards accessible by the second plurality of printed circuit boards via the one or more connection access points.

Any of the aspects herein, wherein position tolerancing of the second plurality of printed circuit boards relative to the first plurality of printed circuit boards is provided by at least one positioning component on the chassis structure, and wherein the at least one positioning component is operable to engage at least one of the first plurality of printed circuit boards and the second plurality of printed circuit boards.

An assembly for stacking a plurality of circuit boards of an electronics package, comprising: a chassis structure; a first printed circuit board (PCB); and one or more additional PCBs, the one or more additional PCBs configured to be coupled to the first PCB, wherein the first PCB is configured to be physically coupled to a first side of the chassis structure and the one or more additional PCBs are configured to be physically coupled to a second side of the chassis structure, the second side opposing the first side.

Any of the aspects herein, wherein a directional force exerted on the one or more additional PCBs is distributed along the chassis structure based at least in part on the one or more additional PCBs being physically coupled to the second side of the chassis structure.

Any of the aspects herein, wherein the one or more additional PCBs are stacked on top of the first PCB.

Any of the aspects herein, wherein the chassis structure is located between the one or more additional PCBs and the first PCB.

Any of the aspects herein, wherein the first side of the chassis structure comprises a bottom side of the chassis structure, and the second side of the chassis structure comprises a top side of the chassis structure.

Any of the aspects herein, wherein the first PCB comprises a motherboard, and the one or more additional PCBs comprise one or more daughter cards.

Any of the aspects herein, wherein the chassis structure comprises one or more connection access points configured to allow one or more connectors of the first PCB to pass through the chassis structure.

Any of the aspects herein, wherein the one or more connectors of the first PCB are configured to provide coupling between the first PCB and the one or more additional PCBs.

Any of the aspects herein, wherein the coupling between the first PCB and the one or more additional PCB comprises electrical coupling, communication coupling, or a combination thereof.

An electronics package, comprising: a coldplate that is configured to provide a top cover surface for the electronics package, wherein the coldplate comprises a chamber with an inlet and an outlet that enable a flow of coolant liquid through the chamber; a heatpipe assembly configured to be coupled to the coldplate; a midplate assembly, comprising: a chassis structure; a first PCB; and one or more additional PCBs, the one or more additional circuit boards configured to be coupled to the first PCB, wherein the first PCB is configured to be physically coupled to a first side of the chassis structure and the one or more additional PCBs are configured to be physically coupled to a second side of the chassis structure, the second side opposing the first side; and a bottom cover, wherein the bottom cover attaches to the coldplate to provide a hermetic seal for the first PCB and the one or more additional PCBs of the midplate.

Any of the aspects herein, wherein a directional force exerted on the one or more additional PCBs by the heatpipe assembly is distributed along the chassis structure based at least in part on the one or more additional PCBs being physically coupled to the second side of the chassis structure.

Any of the aspects herein, wherein the one or more additional PCBs are stacked on top of the first PCB.

Any of the aspects herein, wherein the chassis structure is located between the one or more additional PCBs and the first PCB.

Any of the aspects herein, wherein the midplate assembly further comprises: one or more apertures configured to allow one or more protrusions of the coldplate to pass through the midplate assembly, come into contact with the bottom cover, or a combination thereof.

Any of the aspects herein, wherein the one or more protrusions of the coldplate are configured to absorb heat generated by the first PCB of the midplate assembly.

Any of the aspects herein, wherein the chassis structure of the midplate assembly comprises one or more connection access points configured to allow one or more connectors of the first PCB to pass through the chassis structure.

Any of the aspects herein, wherein the one or more connectors of the first PCB are configured to provide coupling between the first PCB and the one or more additional PCBs.

Any of the aspects herein, wherein the coupling between the first PCB and the one or more additional PCB comprises electrical coupling, communication coupling, or a combination thereof.

A method of assembling an integrated electronics package, comprising: providing an electronics package, comprising: a coldplate that is configured to provide a top cover surface for the electronics package, wherein the coldplate comprises a chamber with an inlet and an outlet that enable a flow of coolant liquid through the chamber; a heatpipe assembly configured to be coupled to the coldplate; a midplate assembly, comprising: a chassis structure; a first PCB; and one or more additional PCBs; and a bottom cover; aligning the heatpipe assembly with the coldplate based at least on one or more alignment pins; coupling the heatpipe assembly to the coldplate; coupling the first PCB to the midplate assembly, wherein the first PCB is physically coupled to a first side of the chassis structure of the midplate assembly; coupling the one or more additional PCBs to the midplate assembly to provide a coupling between the first PCB and the one or more additional PCBs, wherein the one or more additional PCBs are physically coupled to a second side of the chassis structure of the midplate assembly, the second side opposing the first side; coupling the midplate assembly to the bottom cover; and coupling the bottom cover to the coldplate, wherein coupling the bottom cover to the coldplate provides a hermetic seal for the first PCB and the one or more additional PCBs.

Any of the aspects herein, wherein a directional force exerted on the one or more additional PCBs by the heatpipe assembly is distributed along the chassis structure based at least in part on the one or more additional PCBs being physically coupled to the second side of the chassis structure.

Any aspect in combination with any one or more other aspects.

Any one or more of the features disclosed herein.

Any one or more of the features as substantially disclosed herein.

Any one or more of the features as substantially disclosed herein in combination with any one or more other features as substantially disclosed herein.

Any one of the aspects/features/embodiments in combination with any one or more other aspects/features/embodiments.

Use of any one or more of the aspects or features as disclosed herein.

It is to be appreciated that any feature described herein can be claimed in combination with any other feature(s) as described herein, regardless of whether the features come from the same described embodiment.

The details of one or more aspects of the disclosure are set forth in the accompanying drawings and the description below. Other features, objects, and advantages of the techniques described in this disclosure will be apparent from the description and drawings, and from the claims.

The preceding is a simplified summary of the disclosure to provide an understanding of some aspects of the disclosure. This summary is neither an extensive nor exhaustive overview of the disclosure and its various aspects, embodiments, and configurations. It is intended neither to identify key or critical elements of the disclosure nor to delineate the scope of the disclosure but to present selected concepts of the disclosure in a simplified form as an introduction to the more detailed description presented below. As will be appreciated, other aspects, embodiments, and configurations of the disclosure are possible utilizing, alone or in combination, one or more of the features set forth above or described in detail below.

Numerous additional features and advantages of the present disclosure will become apparent to those skilled in the art upon consideration of the embodiment descriptions provided hereinbelow.

### BRIEF DESCRIPTION OF THE DRAWINGS

FIG. 1 shows a top perspective view of an electronics package in accordance with embodiments of the present disclosure;

FIG. 2 shows an exploded perspective view of the electronics package of FIG. 1, in accordance with embodiments of the present disclosure;

FIG. 3A shows a top view of a midplate assembly of the electronics package of FIG. 1 in a first assembled state, in accordance with embodiments of the present disclosure;

FIG. 3B shows a top view of the midplate assembly of the electronics package of FIG. 1 in a second assembled state, in accordance with embodiments of the present disclosure;

FIG. 3C shows a bottom view of the midplate assembly of the electronics package of FIG. 1 in an unassembled state, in accordance with embodiments of the present disclosure;

FIG. 3D shows a bottom perspective view of the midplate assembly of the electronics package of FIG. 1 in a third assembled state, in accordance with embodiments of the present disclosure;

FIG. 3E shows a top perspective view of a midplate assembly of the electronics package of FIG. 1, in accordance with embodiments of the present disclosure;

FIG. 3F shows a top perspective view of a midplate assembly of the electronics package of FIG. 1, in accordance with embodiments of the present disclosure;

FIG. 4 shows a bottom perspective view of a heatpipe assembly of the electronics package of FIG. 1 in an assembled state, in accordance with embodiments of the present disclosure;

FIG. 5 shows a top view of a bottom cover of the electronics package of FIG. 1, in accordance with embodiments of the present disclosure; and

FIG. 6 is a flow diagram of a method or process for assembling the electronics package of FIG. 1, in accordance with embodiments of the present disclosure.

### DETAILED DESCRIPTION

Before any embodiments of the disclosure are explained in detail, it is to be understood that the disclosure is not limited in its application to the details of construction and the arrangement of components set forth in the following description or illustrated in the drawings. The disclosure is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Further, the present disclosure may use examples to illustrate one or more aspects thereof. Unless explicitly stated otherwise, the use or listing of one or more examples (which may be denoted by “for example,” “by way of example,” “e.g.,” “such as,” or similar language) is not intended to and does not limit the scope of the present disclosure.

The ensuing description provides embodiments only, and is not intended to limit the scope, applicability, or configuration of the claims. Rather, the ensuing description will provide those skilled in the art with an enabling description for implementing the described embodiments. It being understood that various changes may be made in the function and arrangement of elements without departing from the spirit and scope of the appended claims.

Various aspects of the present disclosure will be described herein with reference to drawings that may be schematic illustrations of idealized configurations.

Embodiments of the present disclosure will be described in connection with electronics packaging, and in some embodiments, the construction, structure, and arrangement of elements that includes a middle plate architecture that supports a stacking design of processing units.

In some embodiments, the present disclosure describes an electronics package (e.g., an electronics module) that comprises a midplate assembly with a chassis structure (e.g., middle plate architecture). Additionally, the electronics package may include multiple processing units including a first plurality of printed circuit boards or PCBs (e.g., motherboard, main circuit board, etc.) and a second plurality of printed circuit boards or PCBs (e.g., daughter cards, additional circuit boards, PCB daughter cards, etc.), where the second plurality of PCBs are coupled or connected to the first PCB (e.g., via headers, pin headers, sockets, board-to-board connectors, or additional types of connectors, etc.). As described herein, the first plurality of PCBs and the second plurality of PCBs are mounted to the chassis structure of the midplate assembly. Accordingly, the chassis structure may provide spacing between the first plurality of PCBs and the second plurality of PCBs while also distributing any forces or loads applied to any of the PCBs along the chassis structure rather than to the coupled/connected PCBs.

Traditionally, mechanical standoffs are used to mount daughter cards onto a motherboard to form a mezzanine (e.g., tiered) structure where the respective circuit boards (e.g., PCBs) are parallel to each other. Multiple daughter cards can be mounted onto one main motherboard. However, the mechanical standoffs may increase a complexity for constructing electronics modules or packages that include a motherboard and one or more daughter cards that need to be coupled/connected. For example, very tight height tolerances of each individual standoff and between the standoffs as a group, and/or possible threading for mounting screws may be necessary to mount the daughter cards to the motherboard. In some configurations, tolerancing for the screws may be ±0.01 millimeters (±3.9×10⁻⁴ inches). Accordingly, integrating mechanical standoffs may not readily allow for the necessary tolerances.

In addition, where spring-loaded devices are utilized within the electronics package to ensure a minimum or sufficient amount of contact (e.g., thermal contact) occurs between adjacent components, forces supplied on the daughter cards by the springs may transfer too much stress to the motherboards through the mechanical standoffs. For example, a minimum or sufficient amount of thermal contact may be necessary between a cooling structure and the daughter cards to dissipate an amount of heat generated by the daughter cards (e.g., in a surrounding environment) and prevent premature failures in the electronics package and/or shorter life spans of components in the electronics package.

As described herein, an electronics module or package is provided with a midplate assembly comprising a chassis structure (e.g., to serve as a mezzanine structure) located between a first plurality of PCBs (e.g., a motherboard or main PCB) and a second plurality of PCBs (e.g., daughter cards) to function like standoffs. In this design, the motherboard and daughter cards are all mounted to the chassis structure without extra load path through the PCBs. This design allows for customization of a mounting structure or surfaces that are optimized to each individual board. Mounting the motherboard and daughter cards to the chassis structure of the midplate assembly rather than using mechanical standoffs may reduce an assembly tolerance and forces within the entire electronics module/package. Additionally, this design reduces a parts count for the electronics module/package and reduces complexity through higher integration of components into combined assemblies or singular components.

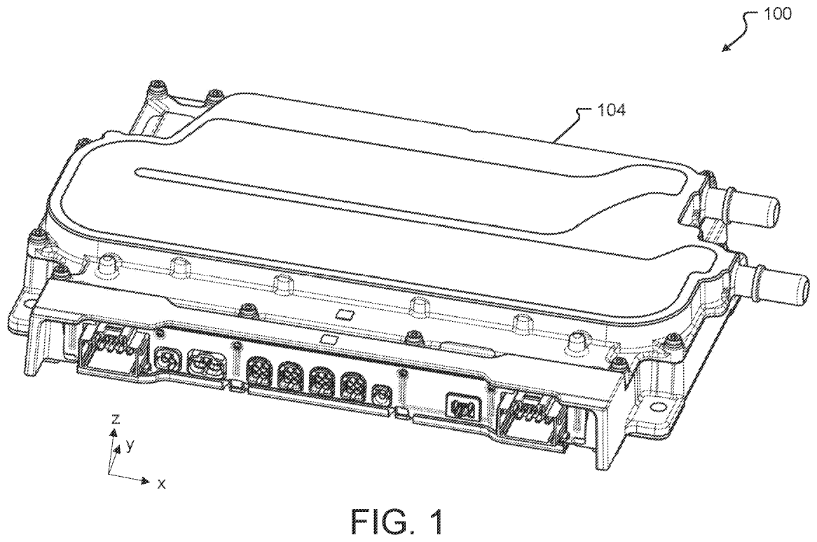

Turning now to FIG. 1, a top perspective view 100 of an electronics package 104 is provided, in accordance with embodiments of the present disclosure. In some embodiments, the electronics package 104 may be designed to provide functions to and/or assist in operating a vehicle. For example, the electronics package 104 may be a compute module for use in a vehicle. In some examples, the functions provided by the electronics package 104 may include critical functions for the vehicle, such as autonomous driving operations, navigation, RADAR, vehicle controls, communications (e.g., vehicle-to-vehicle (V2V) or vehicle-to-everything (V2X) communications), etc. Additionally, the vehicle described herein may include any conveyance or model of a conveyance, where the conveyance was designed for the purpose of moving one or more tangible objects, such as people, animals, cargo, and the like. The term “vehicle” does not require that a conveyance moves or is capable of movement. Typical vehicles may include but are in no way limited to electric vehicles, cars, trucks, motorcycles, busses, automobiles, bicycles, scooters, paved or unpaved surface conveyances, trains, railed conveyances, boats, ships, marine conveyances, submarine conveyances, airplanes, space craft, flying machines, human-powered conveyances, and the like.

As described herein, the electronics package 104 may include or house multiple high-powered processing units (e.g., included on or referred to as PCBs, a motherboard, daughter cards, or a combination thereof), as described in detail further herein. The high-powered processing units may be referred to as system on chips (SOCs) or integrated circuits or may include SOCs. SOCs may be microchips with all necessary electronic circuits and parts for a given system, such as computer chips or chips that enable/provide a system in a vehicle, on a single integrated circuit. For example, the SOCs may perform computations and/or provide other features for operating the vehicle. In some examples, the multiple SOCs may operate together (e.g., or in subsets) to provide features for operating the vehicle, and/or individual SOCs may provide separate features for operating the vehicle. While described in the context of a vehicle, the electronics package 104 described herein may be used for providing other purposes and in other contexts not explicitly described herein.

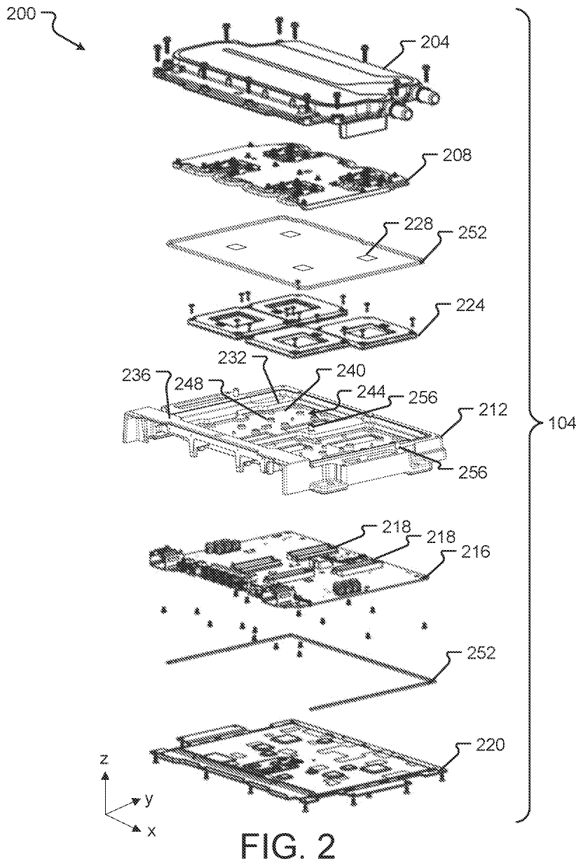

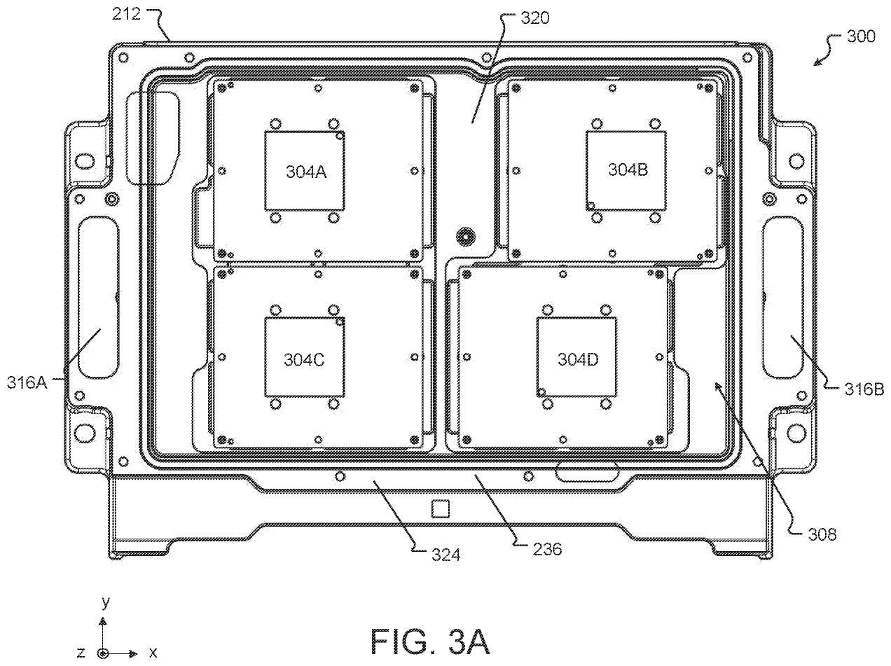

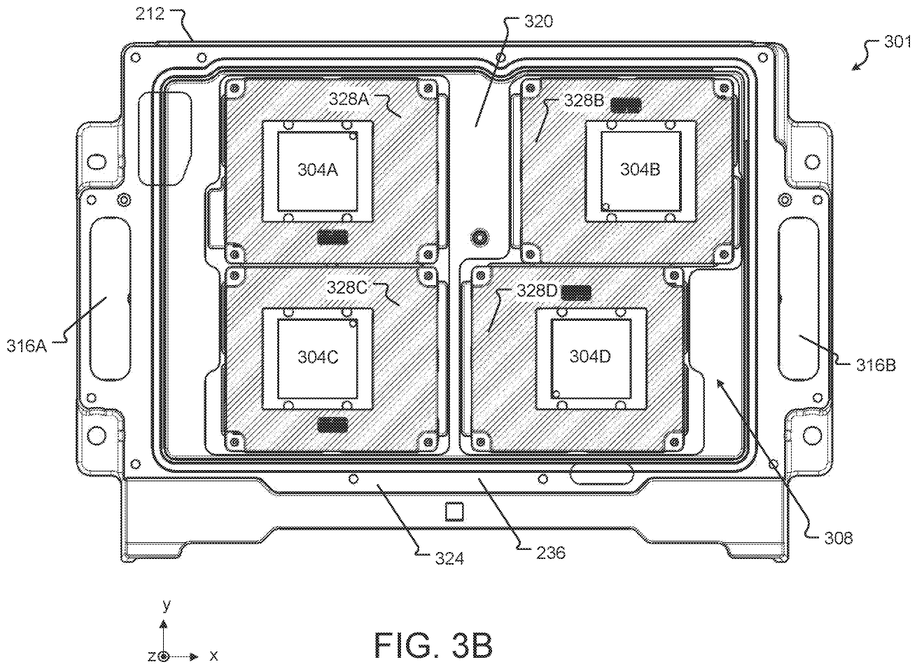

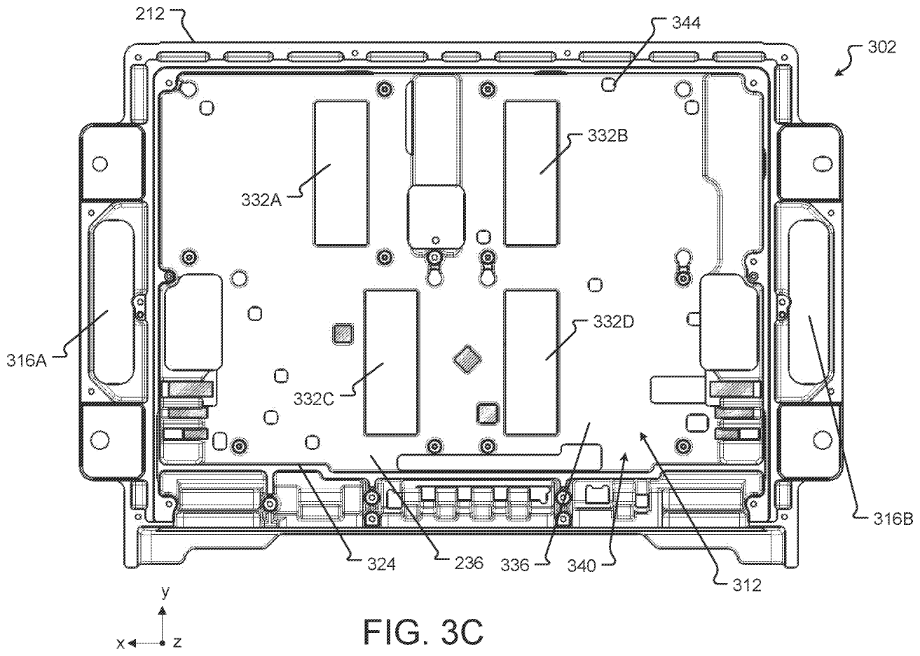

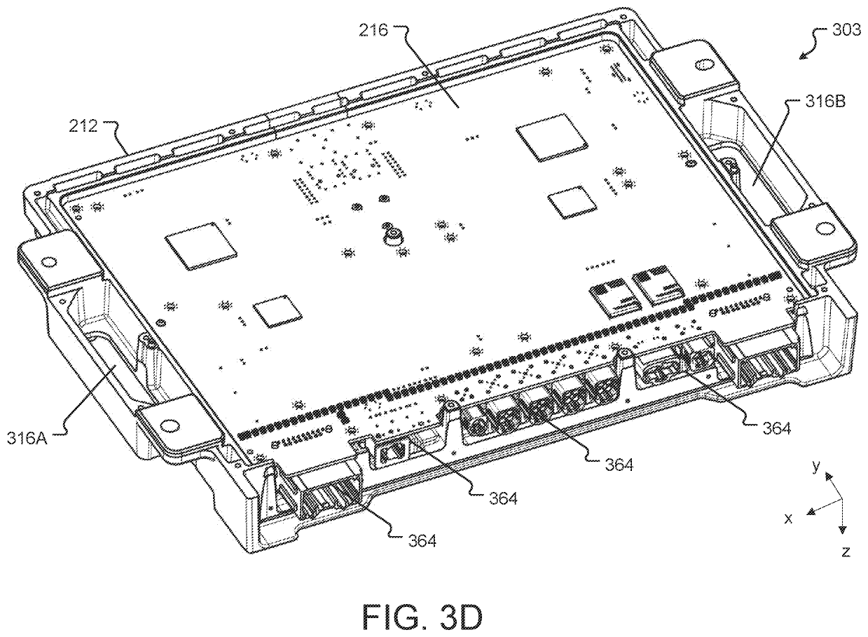

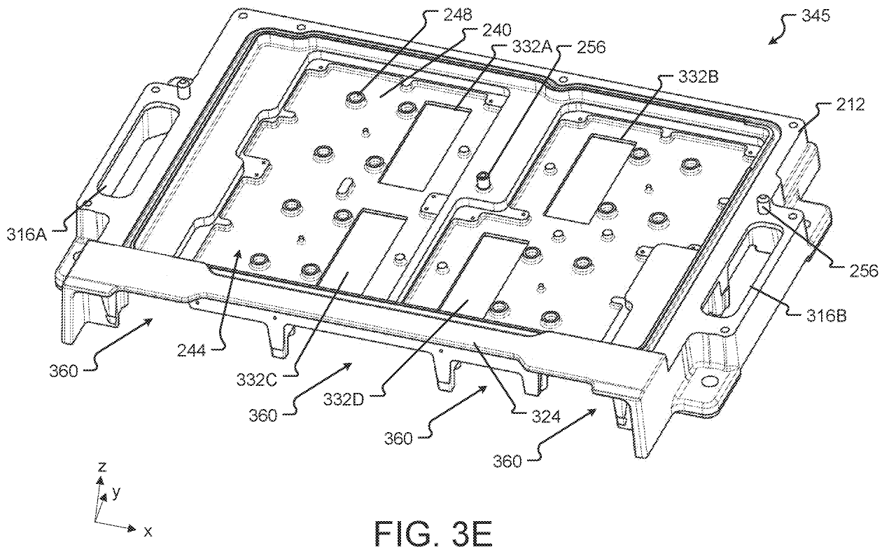

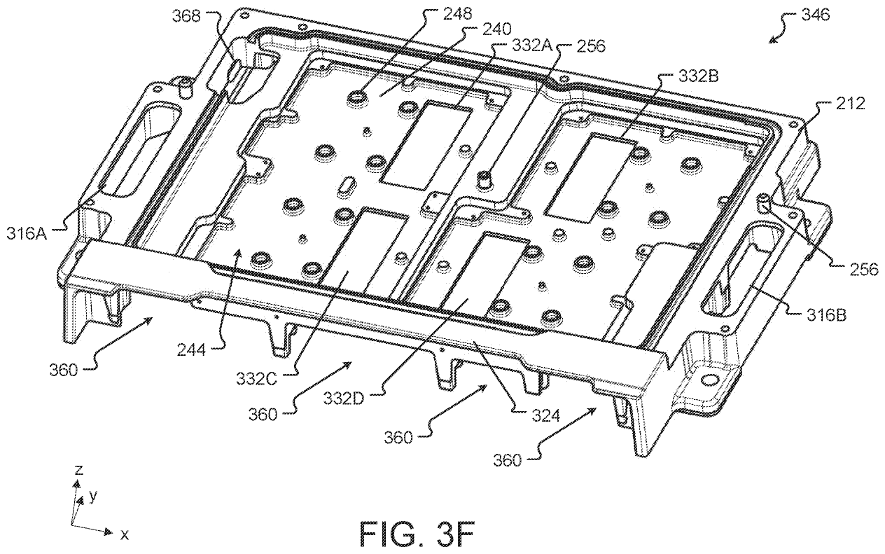

In some embodiments, the electronics package 104 may be part of an overall system where space is limited (e.g., within a vehicle as described previously). As such, it is desirable to minimize a size, shape, and/or overall footprint of the electronics package 104 to ensure there is enough space for additional elements of the overall system. As described in greater detail with reference to FIGS. 2 and 3A-3F, the electronics package 104 implements a stacking design of daughter cards and a motherboard to reduce a size, shape, and overall footprint of the electronics package 104. For example, as described in detail further herein, the daughter cards and motherboard may be mounted to a chassis structure of a midplate assembly in the electronics package 104 instead of traditional mechanical standoffs (e.g., metal spacers, or the like) to provide spacing between the daughter cards and motherboard and to distribute any forces or pressure through the midplate 212 exerted on the daughter cards and motherboard rather than onto the daughter cards and/or motherboard, themselves.

Additionally, the stacking design may enable a more flexible controller layout (e.g., the daughter cards can be laid out in different ways), which may be beneficial for future hardware upgrade operations, and which may reduce upgrade costs. For example, the electronics package 104 may be removed from a system of which the electronics package 104 is a part (e.g., vehicle, vehicle system, etc.), and the daughter cards can be easily accessed for upgrading without having to take the entire electronics package 104 apart.

FIG. 2 depicts an exploded perspective view 200 of an electronics package 104 in accordance with embodiments of the present disclosure. In some examples, the exploded view 200 as described with reference to FIG. 2 may implement aspects of or may be implemented by aspects of FIG. 1. For example, the exploded view 200 of the electronics package may be an exploded view of different components included in the electronics package 104 as described with reference to FIG. 1.

As shown in the exploded view 200, the electronics package 104 may include a coldplate 204, a heatpipe assembly 208, a middle plate structure (or midplate) 212, a first plurality of printed circuit boards 216 (e.g., including, but not limited to, a main or first PCB 216) with connectors 218, and a bottom cover 220. The electronics package 104 may also include thermal spacers 224 and a second plurality of printed circuit boards 228 (e.g., one or more daughter cards or one or more additional PCBs 228), as described in detail further herein. In some examples, the coldplate 204 may be a top cover and/or include a top cover surface for the electronics package 104. Additionally, the coldplate 204 may include a chamber with an inlet and an outlet to enable a flow of coolant liquid through the chamber. For instance, the coolant liquid may be water or another liquid that absorbs heat generated by other components of the electronics package 104 (e.g., the midplate 212, processing units such as the main PCB 216 and the daughter cards 228, integrated circuits, SOCs, etc.) to be dissipated to the surrounding environment or elsewhere external to the electronics package 104. It is noted herein that the first plurality of printed circuit boards 216 and/or the second plurality of printed circuit boards 228 may include 1, 2, . . . up to an N number of printed circuit boards, without departing from the scope of the present disclosure. In addition, it is noted herein that the term “main PCB” is not intended to necessarily reference the primary nature of the PCB 216, but instead may reflect the mother/daughter relationship between the PCB 216 and the PCBs 228 in select embodiments of the present disclosure. Further, it is noted herein that the “main PCB” may itself be a secondary PCB to another more central PCB or a parent PCB.

While in use, the electronics package 104 may generate heat, for example, typically generated by the flow of electric current through one or more resistive elements and/or components of the electronics package 104, such as high-powered processing units described previously (e.g., daughtercards, PCBs, microprocessors, etc.). If the heat generated in the electronics package 104 (e.g., via the high-powered processing units) is not efficiently removed, temperatures of the electronics package 104 may exceed a normal operating range. In some examples, operating the electronics package 104 at temperatures outside of the normal operating range (even periodically) can cause premature failures in the electronics package 104 and/or result in shorter life spans of components in the electronics package 104.

The heatpipe assembly 208 may represent an assembly for providing cooling to a plurality of integrated circuits (e.g., processing units such as processors, daughter cards, PCBs, etc.). In some embodiments, the heatpipe assembly 208 may be coupled to the underside of the coldplate 204. In some examples, the underside of the coldplate 204 and/or a topside of the heatpipe assembly 208 may have a thermal interface material (TIM) (e.g., thermal grease or another compound or type of TIM) applied to their adjacent surfaces, where the TIM or similar performing compound is intended to maximize thermal conductivity between the heatpipe assembly 208 and the coldplate 204. For example, the heatpipe assembly 208 may be configured to absorb heat generated from other components in the electronics package 104 (e.g., the midplate 212, processing units such as the main PCB 216 and other processors, integrated circuits, SOCs, daughter cards, additional PCBs, etc.) and then transfer the absorbed heat to the coldplate 204 based in part on the TIM, where the transferred heat is dissipated away from the electronics package 104 via the coldplate 204 as described above.

In some examples, the coldplate 204 and the heatpipe assembly 208 may be coupled together in a first subassembly of the electronics package 104. It is noted herein, however, that the coldplate 204 and the heatpipe assembly 208 may be a single fabricated (e.g., casted, machined, three-dimensional (3D) printed, or the like), without departing from the scope of the present disclosure.

Additionally, the electronics package 104 may include a second subassembly comprised of the midplate 212, the main PCB 216, and optionally the thermal spacers 224 and/or the daughter cards 228. For example, the midplate 212 may be coupled to the main PCB 216, such that multiple integrated circuits (e.g., daughter cards 228, multiple SOCs, chips, processors, etc.) can be aligned on the midplate 212 coupled (e.g., physically, electrically, communicatively, etc.) to the main PCB 216.

It is noted herein that the bottom cover 220 may be a component of the second subassembly or may be a separate, additional subassembly that couples to one or more of the second assembly or the first assembly as described above, without departing from the scope of the present disclosure.

In some examples, the multiple integrated circuits of the midplate 212 may be parts of respective daughter cards 228 and/or a same daughter card 228 that is physically and/or electrically coupled to the main PCB 216. The daughter card(s) 228 may provide complementary or supplementary functions to the main PCB 216 stored in the electronics package 104. For example, the daughter card(s) 228 may be types of processing units that plug in or are coupled to a motherboard or similar expansion card (e.g., the main PCB 216) to extend features and services of the motherboard or similar expansion card. That is, the daughter card 228 may complement or supplement an existing functionality of a motherboard or an expansion card. The daughter card(s) 228 (and/or the main PCB 216) may, in part, provide a function for a vehicle (e.g., electrical vehicle) but is not limited to such examples.

Additionally, the daughter card(s) 228 may require high amounts of power to provide the complementary/supplementary functions, where the high amounts of power cause heat to be generated in the electronics package 104 based, in part, on the flow of electric current needed to supply the high amounts of power passing through the integrated circuits of the midplate 212 (e.g., and/or other resistive elements and/or components of the midplate 212). Accordingly, the heatpipe assembly 208 may be configured to absorb the generated heat from the integrated circuits (e.g., SOCs) of the midplate 212 to prevent temperatures of the electronics package 104 from exceeding normal operating temperatures and, thereby, lessening the chances of premature failures of the electronics package 104 and/or components within the electronics package 104.

In some cases, one or more of the integrated circuits of the midplate 212 (e.g., daughter cards 228) may be different heights than the other integrated circuits of the midplate 212 (e.g., different heights relative to a top surface of the midplate 212). As such, the heatpipe assembly 208 may be a spring-loaded thermal transfer device. For example, the heatpipe assembly 208 may use springs to ensure contact between the individual integrated circuits and respective components of the heatpipe assembly 208 that are configured to absorb the generated heat from the integrated circuits. For instance, the springs may be configured to apply a downward force on the respective components of the heatpipe assembly 208 (e.g., pads, spreader pads, spreaders, cooling pads, etc.) to ensure contact between the daughter cards and the respective components for the respective components to absorb generated heat and pass the heat to the coldplate 204 to be dispersed external to the electronics package 104.

However, the downward force applied by the springs may be passed on to the daughter cards 228 (e.g., one or more of the integrated circuits of the midplate 212). Where the daughter cards 228 are mounted to the main PCB 216 via traditional mechanical standoffs or metal spacers, the force exerted on the daughter cards can be passed to the main PCB 216, which potentially causes damage to the main PCB 216. As described herein, the midplate 212 instead includes a chassis structure 232 to which the daughter cards 228 and the main PCB 216 are mounted (e.g., on either side of the chassis structure 232) and a secondary chassis structure 236 (e.g., which may be coupled to the chassis structure 232 and/or integrated or formed with the chassis structure 232), where the daughter cards 228 are located proximate to one or more upper surfaces 240 in one or more upper cavities 244 defined within the chassis structure 232. For example, the one or more upper cavities 244 may be at least partially contoured to conform to the daughter cards 228. Alternatively, the shape of the one or more upper cavities 244 may be independent of the shape of the daughter cards 228.

It is noted the secondary chassis structure 236 may include one or more apertures, raised portions, grooved portions, or other shaping or contouring to at least partially conform to components of the main PCB 216 and/or the daughter cards 228 including, but not limited to, electrical ports.

It is noted that the daughter cards 228 may rest or are seated on the one or more upper surfaces 240 within the upper cavities 244 and/or on one or more protrusions 248 extending upward from the one or more upper surfaces 240, such that any pressure or force exerted on the daughter cards 228 (e.g., via the springs and pads of the heatpipe assembly 208 where spring-loaded) will be distributed about the midplate 212 and the chassis structure 232 instead of directly onto the main PCB 216. In some non-limiting examples, where fasteners are used to secure the daughter cards 228 to the midplate 212, the fasteners may engage the one or more protrusions 230. The midplate 212 is shown and described in greater detail with reference to FIGS. 3A-3F.

It is noted that the midplate 212 may be fabricated by casting, machining, three-dimensional (3D) printing, welding or other affixing techniques, or another fabrication technique. The midplate 212 may be fabricated in a single step or sets of steps. The midplate 212 may required pre- and/or post-processing before, during, and/or after fabrication.

The midplate 212 and the main PCB 216 may be coupled to form the second subassembly. Optionally, the combined midplate 212 with the main PCB 216 may be coupled to the bottom cover 220 when forming the second subassembly, or the bottom cover 220 is a separate component or third subassembly to couple to the second subassembly, without departing from the scope of the present disclosure. Additionally, any daughter cards 228, integrated circuits, processing units, etc. may be coupled or connected to the main PCB 216 on a different (e.g., an opposite) side of the midplate 212 than a side that the main PCB 216 is coupled to the midplate 212. For example, the main PCB 216 may be coupled to a bottom side of the midplate 212 (e.g., a bottom side of the chassis structure 232), and the daughter cards 228 may be coupled to a top side of the midplate 212 (e.g., top side of the chassis structure 232). It is noted the top and bottom sides of the chassis structure 232 (and thus the midplate 212) are illustrated in FIGS. 3A-3F and described in further detail herein). In some examples, the daughter cards 228 may be coupled to the midplate 212 prior to coupling the combined midplate 212 with the main PCB 216 to the bottom cover 220. In other examples, the daughter cards 228 may be coupled to the midplate 212 after the combined midplate 212 with the main PCB 216 is coupled to the bottom cover 220.

The first subassembly comprising the coldplate 204 and the heatpipe assembly 208 may then be coupled to the second subassembly comprising the midplate 212, the main PCB 216, and optionally the bottom cover 220 (where the bottom cover 220 is part of the second subassembly). Alternatively, the bottom cover 220 may be coupled to the combined first subassembly and the second subassembly, instead of being coupled to the second assembly prior to the coupling of the first subassembly.

The electronics package 104 may also comprise a plurality of other components that fit between the other components described above. For example, the electronics package 104 may include one or more gaskets or o-rings 252 (e.g., a pre-formed silicone ring within a channel or groove in the midplate 212, coldplate 204, and/or bottom cover 220), additional thermal spacers, clamps, and/or other additional components. For instance, the additional components may be placed between or surrounding the coldplate 204 and the heatpipe assembly 208. In addition, the additional components may be placed between or surrounding the midplate 212 and the main PCB 216. Further, the additional components may be placed between or surrounding the main PCB 216 and the bottom cover 220, between or surrounding the first subassembly and the second subassembly (e.g., substantially between or surrounding the heatpipe assembly 208 and the midplate 212. Further, the additional components may be placed between or surrounding the second subassembly and the bottom cover 220 (e.g., where the second subassembly does not include the bottom cover 220) In some examples, the plurality of other components may be configured to ensure fluid (e.g., water, air, etc.) and/or particulates (e.g., dust, or other particles) do not get in between any of the components of the electronics package 104 (e.g., a hermetic seal is provided to the processing units, integrated circuits, SOCs, the main PCB 216, the daughter cards 228, etc.). Additionally, the plurality of other components may provide other forms of protection to the components of the electronics package 104. For example, the plurality of other components may provide structural support within the electronics package 104 (e.g., to prevent any of the components from being compressed or distorted), spacing between the components (e.g., to prevent heat from being trapped in different areas of the electronics package 104), electromagnetic interference (EMI) protection (e.g., conductive graphite fabric over a foam, or the like, for purposes of ground conducting), or other forms of protection not described herein and outside the scope of the present disclosure. Additionally, the electronics package 104 may include a plurality of screws not explicitly listed or described herein for adjoining any given components of the electronics package 104.

In some embodiments, the midplate 212 includes one or more positioning components 256. For example, the one or more positioning components 256 may engage with corresponding features on the main PCB 216 and/or the daughter cards 228. By way of another example, the one or more positioning components 256 may engage with corresponding features on the coldplate 204 and/or the bottom cover 220. It is noted that position tolerancing of the daughter boards 228 relative to the main PCB 216 may be provided by the one or more positioning components 256, and that the one or more positioning components 256 may engage at least one of the main PCB 216 and the daughter cards 228. In this regard, “floating” connectors 218 that allow for deflecting or shifting of components may be used between the main PCB 216 and the daughter cards 228, in combination with other rigid or semi-rigid x-y positioning or tolerancing features such as the positioning components 256. In some non-limiting example, the positioning components 256 may include, but are not limited to, datum pins or recesses in the midplate 212.

It is noted herein that references to first and second, upper and lower, etc. should not be understood as limiting on a particular set of printed circuit boards, cavities, directions, and the like. For example, the main PCB 216 (or plurality of printed circuit boards 216) may be considered the first or second plurality of printed circuit boards inserted within a first or second plurality of cavities from a first or second direction (or any direction), without departing from the scope of the present disclosure. By way of another example, example, the daughter cards 228 (or plurality of printed circuit boards 228) may be considered the first or second plurality of printed circuit boards inserted within a first or second plurality of cavities from a first or second direction (or any direction), without departing from the scope of the present disclosure.

FIG. 3A depicts a top view 300 of a midplate assembly of an electronics package in a first assembled state in accordance with embodiments of the present disclosure. In some examples, the top view 300 as described with reference to FIG. 3A may implement aspects of or may be implemented by aspects of FIGS. 1 and 2. For example, the top view 300 of the midplate assembly may be a view of the midplate 212 as described with reference to FIG. 2, which may be part of the electronics package 104 as described with reference to FIGS. 1 and 2. In some examples, as described previously, the midplate 212 may comprise a chassis structure 232.

As described herein, the midplate 212 may implement a stacking design for stacking one or more daughter cards 304 (e.g., the daughter cards 228 as described with reference to FIG. 2) on top of a motherboard (e.g., the main PCB 216 as described with reference to FIG. 2). It should be understood that any embodiments directed to the daughter cards 228 may be directed to the daughter cards 304, and vice versa, unless otherwise noted.

The one or more daughter cards 304 (e.g., additional PCBs) may be mounted to an upper side 308 (e.g., top side) of the chassis structure 232 of the midplate 212. As will be described with reference to FIGS. 3C and 3D, the motherboard (e.g., main PCB 216) may be mounted to a lower side 312 (e.g., bottom side) that opposes the upper side 308 of the chassis structure 232 of the midplate 212. Additionally, the midplate 212 may include one or more apertures 316. For example, the midplate 212 may include a first aperture 316A and a second aperture 316B on opposite sides of the midplate 212 (e.g., left side and right side). In some embodiments, the apertures 316 may enable components of the coldplate 204 and/or the heatpipe assembly 208 as described with reference to FIG. 2 to be in closer proximity to the motherboard (e.g., the main PCB 216) to absorb heat generated by the motherboard to provide a heat dissipation route for the motherboard (e.g., for the main PCB 216).

In the non-limiting example of FIG. 3A, four (4) daughter cards 304 are mounted to the chassis structure 232 of the midplate 212, including a first daughter card 304A, a second daughter card 304B, a third daughter card 304C, and a fourth daughter card 304D. As used herein, the daughter cards 304 may include or may be referred to as processing units such as, but not limited to, SOCs. In some embodiments, the processing units may be located on any number of separate PCBs or they may be all located on a same PCB (e.g., separate daughter cards or a same daughter card). For example, the number of processing units/SOCs in the electronics package 104 may be greater than or equal to a number of PCBs in the electronics package 104. In some embodiments, the multiple individual processing units may include four (4) processing units. Additionally, or alternatively, any given number of processing units (e.g., less than four (4) processing units or greater than four (4) processing units) may be included in the electronics package 104 and mounted to the midplate 212.

In some embodiments, the chassis structure 232 of the midplate 212 includes one or more separators 320 that are either fabricated with a frame 324 or separately formed and inserted in and/or coupled to the frame 324. The combination of the frame 324 and the one or more separators 320 for the chassis structure 232 may segment the upper side 308 including specifically-defined areas for one or more of the daughter cards 304.

FIG. 3B depicts a top view 301 of a midplate assembly of an electronics package 104 in a second assembled state in accordance with embodiments of the present disclosure. In some examples, the top view 301 as described with reference to FIG. 3B may implement aspects of or may be implemented by aspects of FIGS. 1, 2, and 3A. For example, the top view 301 of the midplate assembly may be a view of the midplate 212 as described with reference to FIGS. 2 and 3A, which may be part of the electronics package 104 as described with reference to FIGS. 1 and 2.

In some embodiments, the first assembled state as described with reference to FIG. 3A may include the daughter cards 304 being mounted to the chassis structure 232 of the midplate 212. Subsequently, the second assembled state as described and shown in the example of FIG. 3B may include one or more thermal spacers 328 (e.g., the thermal spacers 224 as described with reference to FIG. 2) coupled to the chassis structure 232 of the midplate 212, and at least partially surrounding the daughter cards 304. It should be understood that any embodiments directed to the thermal spacers 224 may be directed to the thermal spacers 328, and vice versa, unless otherwise noted.

The thermal spacers 328 may have a TIM applied to their top sides to assist in transferring heat generated from the daughter cards 304 to the heatpipe assembly 208 and coldplate 204, as described and shown in FIG. 2. Additionally, the thermal spacers 328 may provide physical protection to different components of the daughter cards 304.

In the example of FIG. 3B, a respective thermal spacer 328 is provided for each of the daughter cards 304. For example, a first thermal spacer 328A is provided for the first daughter card 304A, a second thermal spacer 328B is provided for the second daughter card 304B, a third thermal spacer 328C is provided for the third daughter card 304C, and a fourth thermal spacer 328D is provided for the fourth daughter card 304D. Additionally or alternatively, although not shown, the number of thermal spacers 328 may be less than the number of daughter cards 304. For example, one thermal spacer 328 may be provided for multiple daughter cards 304.

In some embodiments, the combination of the frame 324 and the one or more separators 320 for the chassis structure 232 may segment the upper side 308 into specifically-defined areas for one or more of the daughter cards 304 and the corresponding thermal spacer 328.

FIG. 3C depicts a bottom view 302 of a midplate assembly of an electronics package in an unassembled state in accordance with embodiments of the present disclosure. In some examples, the bottom view 302 as described with reference to FIG. 3C may implement aspects of or may be implemented by aspects of FIGS. 1, 2, 3A, and 3B. For example, the bottom view 302 of the midplate assembly may be a view of the midplate 212 as described with reference to FIGS. 2, 3A, and 3B, which may be part of the electronics package 104 as described with reference to FIGS. 1 and 2. In some examples, the bottom view 302 may represent an unassembled state for the midplate 212 where the daughter cards 304, the motherboard (e.g., the main PCB 216), and the thermal spacers 328 as described with reference to FIGS. 2, 3A, and 3B have not been coupled to the midplate 212.

As shown in the example of FIG. 3C, the midplate 212 may include one or more connection access points 332 (e.g., additional apertures or through-holes) within one or more lower surfaces 336 in one or more lower cavities 340 defined within the chassis structure 232 (e.g., such as within the frame 324) in the lower side 312. The one or more connection access points 332 may enable the connection or coupling of the daughter cards 304 in the one or more upper cavities 244 to the motherboard (e.g., the main PCB 216 as illustrated in FIG. 2) in the one or more lower cavities 340, such that the connection access points 332 operable as pass-through holes or connections between the one or more upper cavities 244 and the one or more lower cavities 340. For example, as described previously, in an assembled state, the midplate 212 may comprise the daughter cards 304 being mounted to the upper side 308 of the chassis structure 232 of the midplate 212 and the motherboard being mounted to the lower side 312 of the chassis structure 232. Accordingly, the one or more connection access points 332 may allow for connectors 218 of the motherboard (e.g., headers, pin headers, sockets, board-to-board connectors, high-speed connectors, or additional types of connectors) to pass through the chassis structure 232 of the midplate 212 so that the daughter cards 304 can be connected or coupled to the motherboard, and/or allow for connectors of the daughter cards 304 to pass through the chassis structures 232 of the midplate 212 to connect with the motherboard. It is noted herein that the arrangement of the main PCB 216 and the daughter cards 304 may be different including, but not limited to, the main PCB 216 being positioned within the one or more upper cavities 244 and the daughter cards 304 being positioned within the one or more lower cavities 340, without departing from the scope of the present disclosure.

While four (4) connection access points 332 (e.g., a first connection access point 332A, a second connection access points 332B, a third connection access point 332C, and a fourth connection access point 332D) are shown in the example of FIG. 3C, it is understood that the number of connection access points 332 may be different than four (4) (e.g., fewer or more than 4). In some embodiments, the number of connection access points 332 may correspond to the number of daughter cards 304 configured, needed, or used in the electronics package 104.

It is noted that the motherboard (e.g., the main PCB 216) as illustrated in FIG. 2 may rest or is seated on the one or more lower surfaces 336 and/or on one or more protrusions 344 extending downward from the one or more lower surfaces 336, such that any pressure or force exerted on the motherboard is distributed about the midplate 212 and the chassis structure 232. Where fasteners are used to secure the motherboard to the midplate 212, the fasteners may engage the one or more protrusions 344.

FIG. 3D depicts a bottom perspective view 303 of a midplate assembly of an electronics package in a third assembled state in accordance with embodiments of the present disclosure. In some examples, the bottom perspective view 303 as described with reference to FIG. 3D may implement aspects of or may be implemented by aspects of FIGS. 1, 2, 3A, 3B, and 3C. For example, the bottom perspective view 303 of the midplate assembly may be a view of the midplate 212 as described with reference to FIGS. 2, 3A, 3B, and 3C, which may be part of the electronics package 104 as described with reference to FIGS. 1 and 2.

The third assembled state as described in the example of FIG. 3D may include the main PCB 216 as described with reference to FIG. 2 (e.g., a motherboard) being mounted to the chassis structure 232 of the midplate 212. In some embodiments, the main PCB 216 may be mounted to the chassis structure 232 of the midplate 212 (e.g., installed) directly in the z-direction to prevent interference with components of the main PCB 216. For example, any connectors 218 on the main PCB 216 for making connections between the main PCB 216 and the daughter cards 304 may be positioned in line with the connection access points 332 (as illustrated in FIG. 3C) to prevent possible damage or interference to the connectors 218 and other components of the main PCB 216. In some embodiments, the third assembled state may be achieved prior to the first assembled state, the second assembled state, or both as described with reference to FIGS. 3A and 3B. That is, the main PCB 216 may be mounted to the midplate 212 first, then the daughter cards 304 may be coupled to the main PCB 216 and mounted to the midplate 212, and then the thermal spacers 328 may be mounted to the midplate 212 at least partially surrounding the daughter cards 304. Additionally or alternatively, the first assembled state, the second assembled state, and the third assembled state may be achieved in a different order.

The main PCB 216 may generate heat similar to the daughter cards 304 (e.g., based on electrical current passing through resistive elements and/or other elements of the main PCB 216). Accordingly, this heat must also be dissipated external to the electronics package 104 to prevent possible malfunctions and damage or to prevent reducing the lifespan of the electronics package 104. As described previously, the apertures 316 may enable parts of the coldplate 204 to pass through the chassis structure 232 of the midplate 212 to absorb the heat generated by the main PCB 216 (e.g., the apertures 316 provide a heat dissipation route for the main PCB 216). By allowing the parts of the coldplate 204 to pass through the chassis structure 232 of the midplate 212, an overall height of the electronics package 104 may be reduced, which is beneficial because the electronics package 104 can fit into tighter spaces while still maintaining desirable qualities with respect to thermal conductivity and heat dissipation.

FIG. 3E depicts a top perspective view 345 of a midplate assembly in accordance with embodiments of the present disclosure. In some examples, the top perspective view 345 as described with reference to FIG. 3E may implement aspects of or may be implemented by aspects of FIGS. 1, 2, 3A, 3B, 3C, and 3D. For example, the top perspective view 345 of the midplate assembly may be a view of the midplate 212 as described with reference to FIGS. 2, 3A, 3B, 3C, and 3D, which may be part of the electronics package 104 as described with reference to FIGS. 1 and 2.

FIG. 3E illustrates the midplate 212 with the frame 324 including the upper surface 240 and corresponding upper cavities 244, the protrusions 248, the positioning components 256, the apertures 316A, 316B, and the connection access points 332A-332D. The frame 324 includes port cavities 360 that are at least partially contoured to conform to connectors 364 (e.g., as illustrated in FIG. 3D) that are part of the printed circuit boards (e.g., the main PCB 216).

FIG. 3F depicts a top perspective view 346 of a midplate assembly in accordance with embodiments of the present disclosure. In some examples, the top perspective view 346 as described with reference to FIG. 3F may implement aspects of or may be implemented by aspects of FIGS. 1, 2, 3A, 3B, 3C, 3D, and 3E. For example, the top perspective view 346 of the midplate assembly may be a view of the midplate 212 as described with reference to FIGS. 2, 3A, 3B, 3C, 3D, and 3E, which may be part of the electronics package 104 as described with reference to FIGS. 1 and 2.

FIG. 3F illustrates the midplate 212 with the frame 324 including the upper surface 240 and corresponding upper cavities 244, the protrusions 248, the positioning components 256, the apertures 316A, 316B, the connection access points 332A-332D, and the port cavities 360. The frame 324 includes a cutout 368 that passes through the frame 324 and between the upper and lower surfaces of the midplate 212. In some embodiments, the cutout 368 is usable for passage of or access to electrical connectors, passage of or access to thermal transfer components, and/or positioning of the assembled coldplate 204 and heatpipe assembly 208 and/or the bottom cover 220 (e.g., as illustrated in FIG. 2) relative to the midplate 212. For instance, the cutout 368 may be utilized for debugging components of the electronics package 104 when being assembled, when fully assembled, and/or during repair. It is noted the one or more cutouts 368 may align with corresponding cutouts or protrusions of the assembly coldplate 204 and heatpipe assembly 208 and/or the bottom cover 220. In addition, it is noted that the one or more cutouts 368 may be positioned within the frame 324 to not interfere with the positioning of the main PCB 216 and/or the daughter cards 228/304, as described throughout the present disclosure. It is noted that FIG. 3F includes the cutout 368, whereas FIGS. 3A-3E do not include the cutout 368, but that the midplate 212 including the cutout 368 of FIG. 3F may similarly be used with the electronics package 104 of FIGS. 1 and 2, without departing from the scope of the present disclosure.

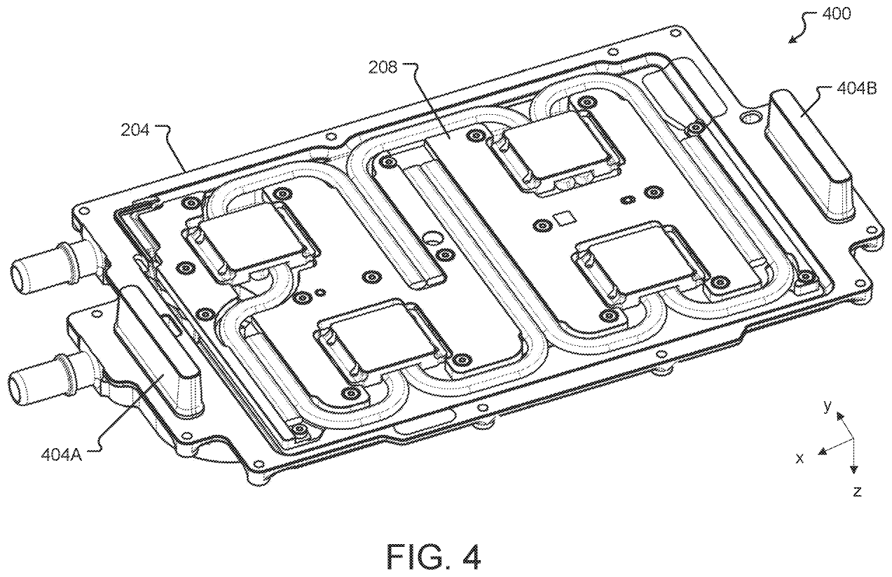

FIG. 4 depicts a bottom perspective view 400 of a heatpipe assembly of an electronics package in an assembled state in accordance with embodiments of the present disclosure. FIG. 4 may implement aspects of or may be implemented by aspects of FIGS. 1, 2, and 3A-3F. For example, the bottom perspective view 400 may be a view of the coldplate 204 and the heatpipe assembly 208 assembled together for the electronics package 104 as described with reference to FIGS. 1-3D.

The assembled coldplate 204 and heatpipe assembly 208 may include one or more protrusions 404 (e.g., a first protrusion 404A and a second protrusion 404B). As described previously with reference to FIGS. 3A and 3D, the main PCB 216 may generate heat similar to the daughter cards 304. Accordingly, the protrusions 404 may be configured to pass through apertures in the midplate 212 (e.g., the apertures 316 as shown and described in the examples of FIGS. 3A-3F) to be in close proximity to the main PCB 216, such that the protrusions 404 can absorb heat generated by the main PCB 216 and provide a heat dissipation route for the generated heat.

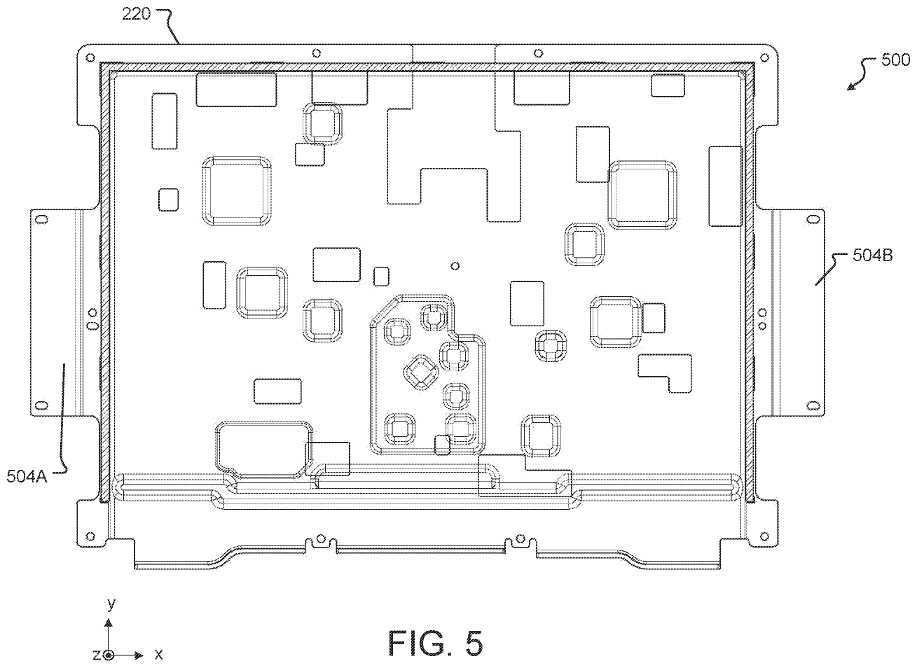

FIG. 5 depicts a top view 500 of a bottom cover of an electronics package in an assembled state in accordance with embodiments of the present disclosure. FIG. 5 may implement aspects of or may be implemented by aspects of FIGS. 1, 2, 3A-3F, and 4. For example, the top view 500 may be a view of the bottom cover 220 for the electronics package 104 as described with reference to FIGS. 1-4. In part, the bottom cover 220 may provide structural support for the electronics package 104, as well as a hermetic seal to prevent fluid or particulates from getting inside the electronics package 104.

Additionally, the bottom cover 220 may include one or more surfaces 504 (e.g., a first surface 504A and a second surface 504B). The surfaces 504 may provide a proximate contact surface for the protrusions 404 of the coldplate 204 and heatpipe assembly 208 as described in the example of FIG. 4. For example, the protrusions 404 may pass through the apertures 316 of the midplate 212 and come into contact with or be within close proximity to the surfaces 504 to assist in absorbing heat generated by the main PCB 216. For example, portions of the main PCB 216 may be in contact with the bottom cover 220, where heat generated by the main PCB 216 is distributed or goes across the bottom cover 220. Accordingly, the surfaces 504 may provide a heat dissipation route for the generated heat from the bottom cover 220 and the main PCB 216 to the coldplate 204 for the heat to be dissipated external to the electronics package 104.

In some embodiments, the bottom cover 220 and/or the coldplate 204 includes one or more apertures which may be used to couple the bottom cover 220 to the coldplate 204 and/or the midplate 212. For example, a first set of fasteners may be passed through the apertures of the bottom cover 220 to engage aligned apertures in the midplate 212, and a second set of fasteners may be passed through the apertures of the coldplate 204 to engage aligned apertures in the midplate 212.

Alternatively, fasteners may be passed through the apertures of the bottom cover 220 to engage the coldplate 204, including either passing through intervening, aligned apertures in the midplate 212 or causing the midplate 212 to be at least partially contained within an enclosure formed by the coldplate 204 and the bottom cover 220.

Further, fasteners may be passed through the apertures of the coldplate 204 to engage the bottom cover 220, including either passing through intervening, aligned apertures in the midplate 212 or causing the midplate 212 to be at least partially contained within an enclosure formed by the coldplate 204 and the bottom cover 220.

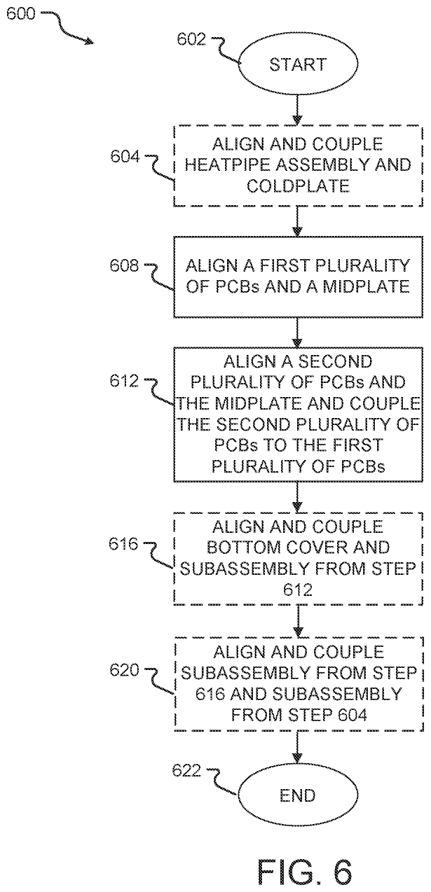

FIG. 6 depicts a flow diagram of a method or process 600 for assembling an electronics package, in accordance with embodiments of the present disclosure. For example, the method or process 600 may be used for forming and assembling an electronics package 104 as described with reference to FIG. 1 that at least includes a midplate 212 as described herein and with reference to FIGS. 2-5. While a general order for the steps of the method or process 600 is shown in FIG. 6, the method or process 600 can include more or fewer steps or can arrange the order of the steps differently (including simultaneously, substantially simultaneously, or sequentially) than those shown in FIG. 6. Generally, the method or process 600 starts with a START operation 602 and ends with an END operation 622. The method or process 600 can be, but is not limited to being, executed as a set of computer-executable instructions executed by an assembly machine (e.g., robotic assembly system, automation assembly system, computer aided drafting (CAD) machine, etc.) and encoded or stored on a computer readable medium. Hereinafter, the method or process 600 shall be explained with reference to the components, devices, assemblies, environments, etc., described in conjunction with FIGS. 1-5.

In a step 604, the heatpipe assembly 208 and the coldplate 204 are aligned and coupled based at least on one or more alignment pins. In some examples, a plurality of sets of springs may be disposed on a top surface of the heatpipe assembly 208 and/or on a bottom surface of the coldplate 204 (meaning, in general, between the coldplate 204 and the heatpipe assembly 208) prior to the aligning of the heatpipe assembly 208 and the coldplate 204, such that the plurality of sets of springs are in contact with the coldplate 204 to exert a directional force in a direction opposing the coldplate 204. In some examples, coupling the heatpipe assembly 208 may exert the directional force via the plurality of sets of springs to move each of the plurality of pads in the direction opposing the coldplate 204. In some examples, thermal interfacing such as TIM may be inserted between the coldplate 204 and the heatpipe assembly 208. It is noted herein the heatpipe assembly 208 and the coldplate 204 form a subassembly when coupled.

It is noted herein that step 604 may be considered optional, such as in a non-limiting example where the coldplate 204 and heatpipe assembly 208 is acquired as a pre-built component for the electronics package 104, without departing from the scope of the present disclosure.

In a step 608, the first plurality of PCBs 216 and the midplate 212 are aligned. Optionally, the first plurality of PCBs 216 may be coupled to the midplate 212.

In a step 612, a second plurality of PCBs (e.g., the one or more daughter cards 228/304 as described with reference to FIGS. 2 and 3A-3F, integrated circuits, processors, etc.) and the midplate 212 are aligned and coupled to the first plurality of PCBs. For example, the second plurality of PCBs 228/304 may be configured to engage with the midplate 212 and/or electrical connectors 218 on the first plurality of PCBs 216 during/after alignment. Optionally, the second plurality of PCBs 228/304 may be coupled to the midplate 212. Accordingly, the first plurality of PCBs 216 and the second plurality of PCBs 228/304 may be electrically and communicatively coupled after both are mounted to the midplate 212. It is noted herein the midplate 212, the first plurality of PCBs 216, and the second plurality of PCBs 228/304 form a subassembly when coupled. In addition, it is noted herein the one or more thermal spacers 224/328 may be aligned and installed with the second plurality of PCBs 228/304, such that the thermal spacers 224/328 are part of the formed subassembly.

In this regard, the first plurality of PCBs 216 and the second plurality of PCBs 228/304 are aligned based on the connectors 218 of the first plurality of PCBs 216 that pass through the one or more apertures 316. The connectors 218 can provide x-y positioning and tolerance to the second plurality of PCBs 228/304, which can access the connectors via the one or more apertures 316. It is noted, however, that the positioning components 256 on the midplate 212 may provide x-y positioning and tolerance to the first plurality of PCBs 216 and/or the second plurality of PCBs 228/304 instead of the connectors 218, including in instances where the connectors 218 are “floating connectors” that are able to deflect or shift in combination with rigid or semi-rigid positioning components 256, without departing from the scope of the present disclosure.

As such, positioning of the second plurality of PCBs 228/304 is not dependent on the placement of fasteners that may be utilized to couple the first plurality of PCBs 216/second plurality of PCBs 228/304 to the midplate 212. Any apertures for fasteners used to couple the first plurality of PCBs 216/second plurality of PCBs 228/304 to the midplate 212 may thus be made oversized or large-bore relative to a fastener (e.g., larger than a shaft diameter, but smaller than a washer diameter or head diameter of the fastener) or positioning components 256, or at least more loosely toleranced than in previous known electronics packages configuration. This allows for the taking up of manufacturing error tolerances (e.g., observed the midplate 212, and the like) and reduce the possibility of applied stresses and transfer of forces that may damage the first plurality of PCBs 216/second plurality of PCBs 228/304. This also allows the first plurality of PCBs 216/second plurality of PCBs 228/304 to slightly move relative to the midplate 212, providing a greater chance for alignment with the locations to which the fasteners engage even where there may be manufacturing errors.

In addition, positioning of the first plurality of PCBs 216 and second plurality of PCBs 228/304 being dependent on the connectors 218 or the positioning components 256 may take up tolerancing issues that occur with select components (e.g., the midplate 212) during manufacturing, reducing the need for post-processing of the select components to ensure that the first plurality of PCBs 216 and the second plurality of PCBs 228/304 correctly fit within the electronics package 104. It is noted, however, that the perimeter walls of the one or more upper cavities 244 and the one or more lower cavities 340 can provide supplemental positioning for the first plurality of PCBs 216 and/or the second plurality of PCBs 228/304 where tolerancing is correct in the midplate 212.

In a step 616, the subassembly from step 612 and the bottom cover 220 are aligned and coupled. It is noted herein the bottom cover 220 may be a component of the subassembly from step 612, or that a new subassembly may be formed by coupling the bottom cover 220 to the subassembly from step 612 without departing from the scope of the present disclosure.

In a step 620, the subassembly from step 604 and the subassembly from step 616 are aligned and coupled. In some cases, coupling the bottom cover 220 to the coldplate 204 may result in components of the heatpipe assembly 208 (e.g., pads) coming into contact with a corresponding PCB of the second plurality of PCBs 228/304 of the midplate 212 based on a plurality of sets of springs exerting a directional force opposing the coldplate 204. By having the one or more additional PCBs mounted to the midplate 212, the directional force exerted by the springs onto the one or more additional PCBs may be distributed among a chassis structure 232 of the midplate 212 rather than being passed onto the first plurality of PCBs 216.

In some examples, coupling the bottom cover 220 and the coldplate 204 provides a hermetic seal for the first plurality of PCB 216s and the second plurality of PCBs 228/304 of the midplate 212. In some examples, coupling the bottom cover 220 to the coldplate 204 may also provide a heat dissipation route for heat generated by the first plurality of PCBs 216 based on protrusions of the coldplate 204 that are configured to pass through apertures of the midplate 212, make contact with the bottom cover 220, or both.

It is noted herein that steps 616 and/or 620 may be considered optional, such as in a non-limiting example where the subassembly including the first plurality of PCBs 216, the second plurality of PCBs 228/304, the midplate 212, and optionally the thermal spacers 224/328 are constructed and then provided as a standalone assembly for further builds at another time or location, without departing from the scope of the present disclosure.

In non-limiting examples, one or more steps (e.g., steps 604, 608, 616) may occur in a first direction (e.g., first z-direction), while one or more steps (e.g., steps 612, 620) may occur in a second direction (e.g., a second z-direction substantially opposite the first z-direction). The differing z-directions may require flipping or otherwise reorienting the various components and subassemblies as described throughout the present disclosure.

It is noted herein that the electronics package 104 as described throughout the present disclosure may be taken apart for service. During servicing, some components (e.g., the thermal spacers 224/328) may need to be reapplied along with any non-working components, but that other components of the electronics package 104 may be re-used.

The exemplary systems and methods of this disclosure have been described in relation to electronics packaging and the thermal control of sealed electronics. However, to avoid unnecessarily obscuring the present disclosure, the preceding description omits a number of known structures and devices. This omission is not to be construed as a limitation of the scope of the claimed disclosure. Specific details are set forth to provide an understanding of the present disclosure. It should, however, be appreciated that the present disclosure may be practiced in a variety of ways beyond the specific detail set forth herein.

A number of variations and modifications of the disclosure can be used. It would be possible to provide for some features of the disclosure without providing others. In some embodiments, the present disclosure provides an electrical interconnection device that can be used between any electrical source and destination. While the present disclosure describes connections between battery modules and corresponding management systems, embodiments of the present disclosure should not be so limited.

References in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in conjunction with one embodiment, it is submitted that the description of such feature, structure, or characteristic may apply to any other embodiment unless so stated and/or except as will be readily apparent to one skilled in the art from the description.

Although the present disclosure describes components and functions implemented in the embodiments with reference to particular standards and protocols, the disclosure is not limited to such standards and protocols. Other similar standards and protocols not mentioned herein are in existence and are considered to be included in the present disclosure. Moreover, the standards and protocols mentioned herein, and other similar standards and protocols not mentioned herein are periodically superseded by faster or more effective equivalents having essentially the same functions. Such replacement standards and protocols having the same functions are considered equivalents included in the present disclosure.

The present disclosure, in various embodiments, configurations, and aspects, includes components, methods, processes, systems and/or apparatus substantially as depicted and described herein, including various embodiments, subcombinations, and subsets thereof. Those of skill in the art will understand how to make and use the systems and methods disclosed herein after understanding the present disclosure. The present disclosure, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving ease, and/or reducing cost of implementation.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more embodiments, configurations, or aspects for the purpose of streamlining the disclosure. The features of the embodiments, configurations, or aspects of the disclosure may be combined in alternate embodiments, configurations, or aspects other than those discussed above. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the disclosure.

Moreover, though the description of the disclosure has included description of one or more embodiments, configurations, or aspects and certain variations and modifications, other variations, combinations, and modifications are within the scope of the disclosure, e.g., as may be within the skill and knowledge of those in the art, after understanding the present disclosure. It is intended to obtain rights, which include alternative embodiments, configurations, or aspects to the extent permitted, including alternate, interchangeable and/or equivalent structures, functions, ranges, or steps to those claimed, whether or not such alternate, interchangeable and/or equivalent structures, functions, ranges, or steps are disclosed herein, and without intending to publicly dedicate any patentable subject matter.

The phrases “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

The term “a” or “an” entity refers to one or more of that entity. As such, the terms “a” (or “an”), “one or more” and “at least one” can be used interchangeably herein. It is also to be noted that the terms “comprising”, “including”, and “having” can be used interchangeably.

The term “automatic” and variations thereof, as used herein, refers to any process or operation, which is typically continuous or semi-continuous, done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

The terms “determine,” “calculate,” “compute,” and variations thereof, as used herein, are used interchangeably and include any type of methodology, process, mathematical operation or technique.

What is claimed is:

1. A middle plate structure for an electronics package, comprising:
a chassis structure including a frame;
a first plurality of cavities defined within the frame on a first side of the chassis structure, the first plurality of cavities being configured to receive a first plurality of printed circuit boards from a first direction;
a second plurality of cavities defined within the frame on a second side of the chassis structure, the second plurality of cavities being configured to receive a second plurality of printed circuit boards from a second, different direction; and
one or more connection access points connecting the first plurality of cavities to the second plurality of cavities.

2. The middle plate structure of claim 1, wherein the first plurality of cavities are configured to at least partially contour to conform to the first plurality of printed circuit boards, wherein the second plurality of cavities are configured to at least partially contour to conform to the second plurality of printed circuit boards, and wherein the second plurality of cavities include surfaces upon which the second plurality of printed circuit boards are seated.

3. The middle plate structure of claim 1, the chassis structure further comprising one or more separators, wherein the one or more separators and the frame define the second plurality of cavities.

4. The middle plate structure of claim 1, wherein the second plurality of cavities are configured to receive one or more thermal spacers that are inserted from the second, different direction.

5. The middle plate structure of claim 1, the chassis structure further comprising:
at least one aperture within the chassis structure, wherein the at least one aperture is operable to transfer heat from at least one of the first plurality of printed circuit boards and the second plurality of printed circuit boards to a cooling structure for dissipation into a surrounding environment.

6. The middle plate structure of claim 1, wherein a plurality of connectors electrically connect the first plurality of printed circuit boards to the second plurality of printed circuit boards via the one or more connection access points, and wherein position tolerancing of the second plurality of printed circuit boards relative to the first plurality of printed circuit boards is provided by the plurality of connectors on the first plurality of printed circuit boards accessible by the second plurality of printed circuit boards via the one or more connection access points.

7. The middle plate structure of claim 1, wherein position tolerancing of the second plurality of printed circuit boards relative to the first plurality of printed circuit boards is provided by at least one positioning component on the chassis structure, and wherein the at least one positioning component is operable to engage at least one of the first plurality of printed circuit boards and the second plurality of printed circuit boards.

8. The middle plate structure of claim 1, wherein the second, different direction is an opposite direction to the first direction.

9. An electronics package, comprising:
a first plurality of printed circuit boards;
a second plurality of printed circuit boards; and
a middle plate structure, the middle plate structure comprising:
a chassis structure including a frame;
a first plurality of cavities defined within the frame on a first side of the chassis structure, the first plurality of cavities being configured to receive the first plurality of printed circuit boards from a first direction;
a second plurality of cavities defined within the frame on a second side of the chassis structure, the second plurality of cavities being configured to receive the second plurality of printed circuit boards from a second, different direction; and
one or more connection access points connecting the first plurality of cavities to the second plurality of cavities.

10. The electronics package of claim 9, further comprising:
a coldplate;
a heatpipe assembly; and
a bottom cover,
wherein alignment of the coldplate and the middle plate structure positions the heatpipe assembly proximate to the second side of the middle plate structure, and
wherein the bottom cover is operable to be positioned proximate to the first side of the middle plate structure.

11. The electronics package of claim 10, the coldplate comprising at least one protrusion, and the chassis structure comprising at least one aperture within the chassis structure,
wherein the at least one aperture is operable to transfer heat from at least one of the first plurality of printed circuit boards and the second plurality of printed circuit boards via the at least one protrusion for dissipation into a surrounding environment via the heatpipe assembly.

12. The electronics package of claim 9, wherein the first plurality of cavities are configured to at least partially contour to conform to the first plurality of printed circuit boards, wherein the second plurality of cavities are configured to at least partially contour to conform to the second plurality of printed circuit boards, and wherein the second plurality of cavities include surfaces upon which the second plurality of printed circuit boards are seated.

13. The electronics package of claim 9, the chassis structure further comprising one or more separators, wherein the one or more separators and the frame define the second plurality of cavities.

14. The electronics package of claim 9, wherein a plurality of connectors electrically connect the first plurality of printed circuit boards to the second plurality of printed circuit boards via the one or more connection access points, and wherein position tolerancing of the second plurality of printed circuit boards relative to the first plurality of printed circuit boards is provided by the plurality of connectors on the first plurality of printed circuit boards accessible by the second plurality of printed circuit boards via the one or more connection access points.

15. The electronics package of claim 9, wherein position tolerancing of the second plurality of printed circuit boards relative to the first plurality of printed circuit boards is provided by at least one positioning component on the chassis structure, and wherein the at least one positioning component is operable to engage at least one of the first plurality of printed circuit boards and the second plurality of printed circuit boards.

16. The electronics package of claim 9, wherein the second, different direction is an opposite direction to the first direction.

17. A method for assembling an integrated electronics package, the method comprising:
providing a middle plate structure, wherein the middle plate structure comprises:
a chassis structure including a frame;
a first plurality of cavities defined within the frame on a first side of the chassis structure;
a second plurality of cavities defined within the frame on a second side of the chassis structure; and
one or more connection access points connecting the first plurality of cavities to the second plurality of cavities,
aligning a first plurality of printed circuit boards with the first plurality of cavities of the middle plate structure from a first direction;
aligning a second plurality of printed circuit boards with the second plurality of cavities of the middle plate structure from a second, different direction; and
coupling the second plurality of printed circuit boards to the first plurality of printed circuit boards via the one or more connection access points to form a subassembly from the middle plate structure, the first plurality of printed circuit boards, and the second plurality of printed circuit boards.

18. The method of claim 17, further comprising:
aligning a bottom cover with the formed subassembly proximate to the first side of the middle plate structure;
coupling the bottom cover to the formed subassembly;
aligning a coldplate and a heatpipe assembly with the formed subassembly, wherein alignment of the coldplate and the middle plate structure positions the heatpipe assembly proximate to the second side of the middle plate structure; and
coupling the coldplate and the heatpipe assembly to the formed subassembly.

19. The method of claim 17, wherein a plurality of connectors electrically connect the first plurality of printed circuit boards to the second plurality of printed circuit boards via the one or more connection access points, and wherein position tolerancing of the second plurality of printed circuit boards relative to the first plurality of printed circuit boards is provided by the plurality of connectors on the first plurality of printed circuit boards accessible by the second plurality of printed circuit boards via the one or more connection access points.

20. The method of claim 17, wherein position tolerancing of the second plurality of printed circuit boards relative to the first plurality of printed circuit boards is provided by at least one positioning component on the chassis structure, and wherein the at least one positioning component is operable to engage at least one of the first plurality of printed circuit boards and the second plurality of printed circuit boards.
